(19) United States
(12) Patent Application Publication
(10) Pub. No.: US 2012/0075778 A1
(43) Pub. Date: Mar. 29, 2012

(54) ELECTRONIC DEVICE

(75) Inventor: ZI-YU ZHAN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/894,169

(22) Filed: Sep. 30, 2010

(30) Foreign Application Priority Data
Sep. 23, 2010 (CN) 201010289427.X

(51) Int. Cl. H05K 7/00; F16B 43/00

(52) U.S. Cl. 361/679.01; 411/544

(57) ABSTRACT

An electronic device includes an enclosure and a number of screws. Each screw includes a bolt, a head, and a shock-absorbing gasket encircling the bolt. The gasket is made of flexible shock-absorbing material. A top surface and a bottom surface of the shock-absorbing gasket are both wave-shaped. The gasket defines a through hole in a center. A number of flexible protrusions extend from an inside wall of the gasket bounding the through hole. The protrusions press against the bolt of the screw.

### BACKGROUND

1. Technical Field

The present disclosure relates to an electronic device which can operate relatively quietly.

2. Description of Related Art

Nowadays, many electronic devices, such as servers, may generate a lot of noise when they are operating. The noise may influence operator's mood and hurt his/her ears. Therefore there is room for improvement in the art.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic, isometric view of an embodiment of an electronic device, the electronic device including a number of shock-absorbing gaskets.

FIG. 2 is a schematic, isometric view of one shock-absorbing gasket of the electronic device of FIG. 1, together with a screw.

FIG. 3 is a schematic, isometric view of one shock-absorbing gasket of the electronic device of FIG. 1.

FIG. 4 is a side plan view of the electronic device of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

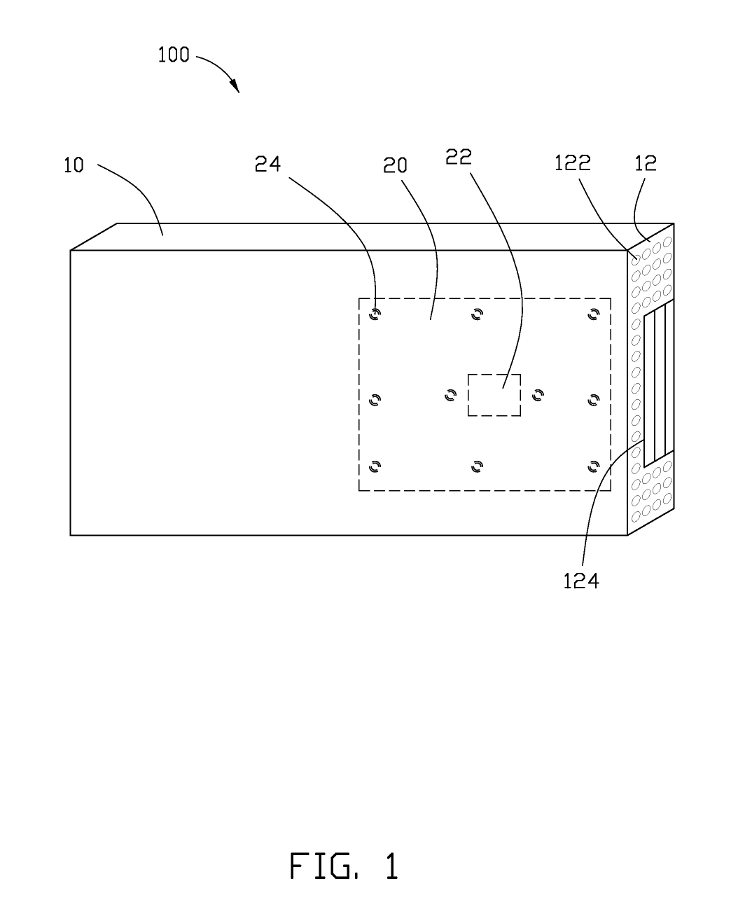

Referring to FIG. 1, an embodiment of an electronic device 100 includes an enclosure 10 and a circuit board 20 arranged in the enclosure 10. The circuit board 20 may include an electronic element 22. For example, the electronic device 100 may be a server, the circuit board 20 may be a motherboard of the server, and the electronic element 22 may be a central processing unit. The circuit board 20 is fixed in the enclosure 10 with a number of screws 24.

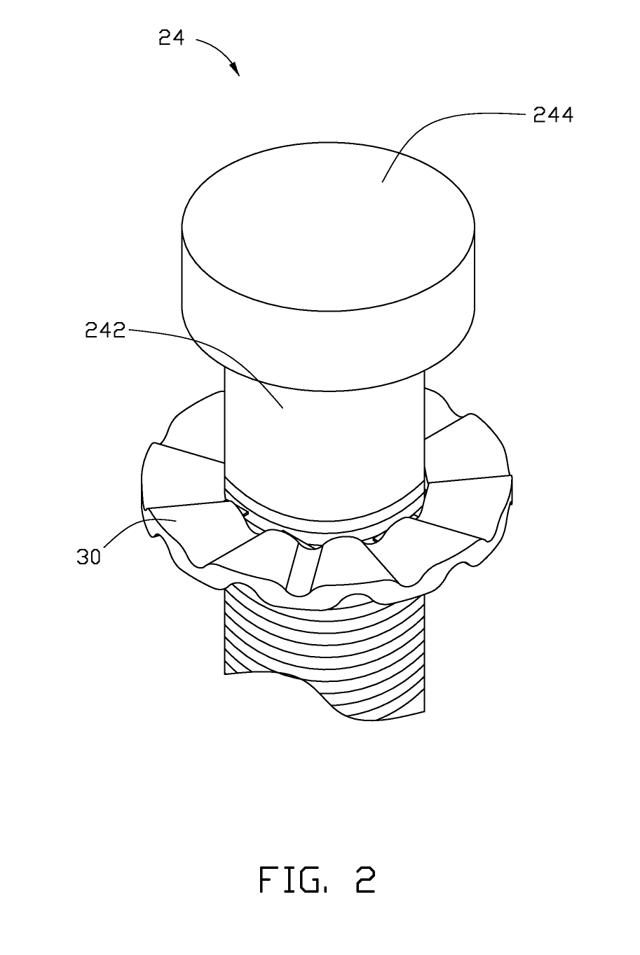

Referring to FIG. 2, each screw 24 includes a threaded bolt 242, a head 244, and a shock-absorbing gasket 30 fitting about the bolt 242.

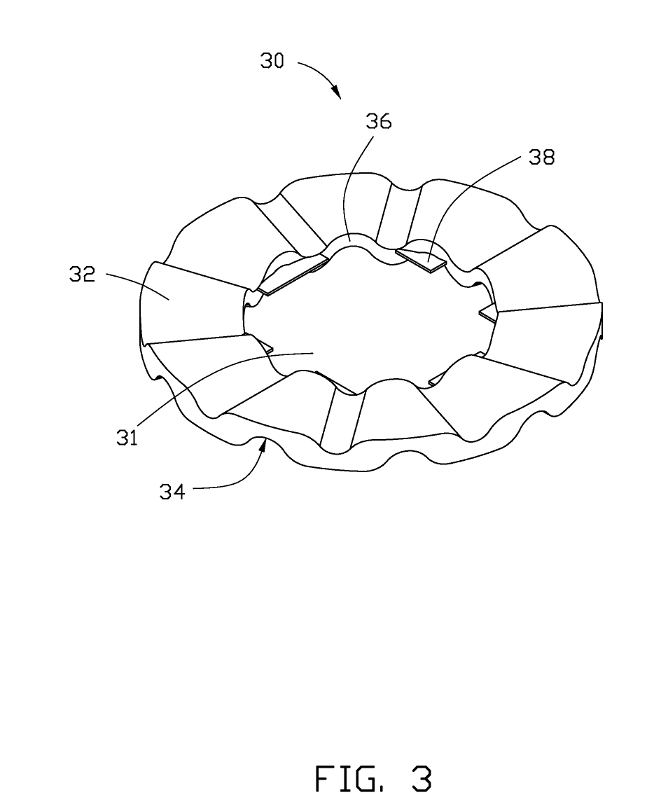

Referring to FIG. 3, the gasket 30 is substantially ring-shaped with a through hole 31 defined in a center of the gasket 30, and is made of flexible shock-absorbing material, such as rubber. The top surface 32 and the bottom surface 34 of the gasket 30 are both wave-shaped, which can increase shock-absorbing area. A number of flexible protrusions 38 extend from an inside wall of the gasket 30 bounding the through hole 31, which press against the bolt 242. In one embodiment, the thickness of the gasket 30 is about two millimeters, and the thickness of the gasket 30 is just the thickness of the sheet of the gasket 30 but not the thickness of the waving shape of the gasket 30 here. The diameter of the gasket 30 is larger than the diameter of the head 244 of the screw 24 by about two millimeters.

In use, the screws 24 fixing the circuit board 20 are fit with the shock-absorbing gaskets 30, respectively, therefore, noise caused by vibration of the electronic device 100 during operation is effectively reduced.

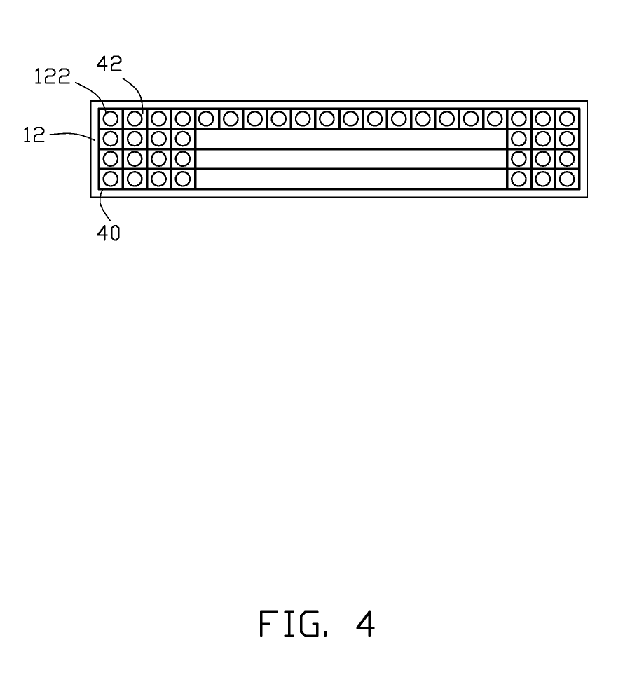

Referring to FIGS. 1 and 4, A number of heat dissipation holes 122 may be defined in a rear sidewall 12 of the enclosure 20, to dissipate heat for the electronic element 22. An opening 124 may be defined in the rear sidewall 12 of the enclosure 20, for exposing some interfaces, such as universal serial buses (USBs). To decrease noise being transmitted to outside of the enclosure 20 through the heat dissipation holes 122 and the opening 124, the electronic device 100 further includes a soundproof net 40 mounted on the rear sidewall 12 of the enclosure 20. The soundproof net 40 defines a number of through holes 42 corresponding to the heat dissipation holes 122 and the opening 124. The soundproof net 40 is made of soundproof material, such as fiberglass, which can block noise escaping through the heat dissipation holes 122 and the opening 124.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. An electronic device comprising:
an enclosure;
an element mounted in the enclosure to execute a function of the electronic device; and
a plurality of screws fixing the element to the enclosure, each of the plurality of screws comprising:
a bolt;
a head; and
a shock-absorbing gasket encircling the bolt of each screw, wherein the gasket is made of flexible shock-absorbing material, and a top surface and a bottom surface of the shock-absorbing gasket are both wave-shaped, the gasket defines a through hole in a center through which the bolt extends, and a plurality of flexible protrusions extends from an inside wall of the gasket bounding the through hole, to press against the bolt.

2. The electronic device of claim 1, where the shock-absorbing gasket is ring-shaped.

3. The electronic device of claim 2, wherein a thickness of the shock-absorbing gasket is about two millimeters, a diameter of the shock-absorbing gasket is larger than a diameter of the head of the screw by about two millimeters.

4. The electronic device of claim 1, wherein the flexible shock-absorbing material is rubber.

5. The electronic device of claim 1, further comprising a soundproof net mounted on a sidewall of the enclosure, wherein the enclosure defines a plurality of holes in the sidewall, the soundproof net defines a plurality of through holes corresponding to the holes of the sidewall, and the soundproof net is made of soundproof material.

6. The electronic device of claim 5, wherein the soundproof material is fiberglass.

7. The electronic device of claim 1, wherein the bolt is threaded.

8. A shock-absorbing gasket to encircle a bolt of a screw, the shock-absorbing gasket comprising:
a wave-shaped top surface and a wave-shaped bottom surface opposite to the top surface, wherein a through hole is defined through centers of the top and bottom surfaces, through which the bolt screw extends; and
a plurality of flexible protrusions extending from an inside wall bounding the through hole, to press against the bolt of the screw;
wherein the shock-absorbing gasket is made of flexible shock-absorbing material.

9. The shock-absorbing gasket of claim 8, wherein the shock-absorbing gasket is ring-shaped.

10. The shock-absorbing gasket of claim 8, wherein the flexible shock-absorbing material is rubber.
